(19) United States
(12) Patent Application Publication
(10) Pub. No.: US 2025/0308615 A1
(43) Pub. Date: Oct. 2, 2025

(54) SEQUENTIAL READ TRACKING IN NON-VOLATILE MEMORY DEVICES

(71) Applicant: Kioxia Corporation, Tokyo (JP)

(72) Inventors: Eyal Nitzan, Tel Aviv (IL); Ofir Kanter, Haifa (IL); Avi Steiner, Tel Aviv (IL); Yasuhiko Kurosawa, Kanagawa (JP); Hanan Weingarten, Tel Aviv (IL)

(73) Assignee: Kioxia Corporation, Tokyo (JP)

(21) Appl. No.: 18/616,318

(22) Filed: Mar. 26, 2024

(51) Int. Cl. G11C 29/50

(52) U.S. Cl. CPC G11C 29/50004; G11C 2029/5004

(57) ABSTRACT

The arrangements disclosed herein relate to systems, methods, non-transitory computer-readable media, and apparatuses including a non-volatile memory and a controller operatively coupled to the non-volatile memory. The controller is to determine information on a number of errors for at least a portion of a page for performing a sequential read operation of a plurality of pages of a block of a plurality of blocks of the non-volatile memory, where the data is read using a first read threshold. The controller is to determine a second read threshold based at least in part on read histogram for the sequential read operation and the information on the number of the errors for at least the portion of the page and the first read threshold.

### TECHNICAL FIELD

The present disclosure relates generally to systems and methods for sequential read tracking in non-volatile memory devices.

### BACKGROUND

As non-volatile memory (e.g., NAND, flash memory, etc.) technology evolves, performance requirements are becoming increasingly challenging. Typically, the performance of a non-volatile memory is measured using metrics such as Input/Output Operations Per Second (IOPS) and throughput (e.g., in MiB/sec). For sequential reads (sequential read operations), performance is typically measured using throughput, and thus, the goal has conventionally been to improve the throughput performance as much as possible.

### SUMMARY

At least one aspect is directed to a system including a non-volatile memory and a controller operatively coupled to the non-volatile memory. The controller is to determine information on a number of errors for at least a portion of a page for performing a sequential read operation of a plurality of pages of a block of a plurality of blocks of the non-volatile memory, where the data is read using a first read threshold. The controller is to determine a second read threshold based at least in part on read histogram for the sequential read operation and the information on the number of the errors for at least the portion of the page.

At least one aspect is directed to at least one non-transitory computer readable medium including one or more instructions stored thereon and executable by a processor to determine information on a number of errors for at least a portion of a page for performing a sequential read operation of a plurality of pages of a block of a plurality of blocks of a non-volatile memory, the data is read using a first read threshold, and determine a second read threshold based at least in part on read histogram for the sequential read operation and the information on the number of the errors for at least the portion of the page.

At least one aspect is directed to a method including determining information on a number of errors for at least a portion of a page for performing a sequential read operation of a plurality of pages of a block of a plurality of blocks of a non-volatile memory, the data is read using a first read threshold, and determining a second read threshold based at least in part on read histogram for the sequential read operation and the information on the number of the errors for at least the portion of the page.

### BRIEF DESCRIPTION OF THE DRAWINGS

FIG. 1 is a graph illustrating example histograms of Voltage Threshold (VT) distribution, according to various arrangements.

FIG. 2 is a graph illustrating example stress increase over time, according to various arrangements.

FIG. 3 is a graph illustrating example block marginal BER versus row number, according to various arrangements.

FIG. 4 is a schematic diagram illustrating an example read threshold estimator, according to various arrangements.

FIG. 5 is a diagram illustrating example system read of a target row across multiple non-volatile memory devices, according to various arrangements.

FIG. 6 is a table illustrating state information represented in buffers by reading multiple page types according to the mapping in FIG. 1, according to various arrangements.

FIG. 7 illustrates extracting directional error information by comparing pre-decode data buffers with post-decode data buffers, according to various arrangements.

FIG. 8 is a flowchart diagram illustrating an example buffer method, according to various arrangements.

FIG. 9 is a diagram illustrating example buffers used in the method shown in FIG. 8, according to various arrangements.

FIG. 10 is a flowchart diagram illustrating an example method for writing an error flag buffer and an error direction buffer, according to various arrangements.

FIG. 11 is a table illustrating an example write policy per data cell for an error flag buffer and an error direction buffer, according to various arrangements.

FIG. 12 is a table illustrating an example buffer method, according to various arrangements.

FIG. 13 is a diagram illustrating tracking, one block at a time, according to various arrangements.

FIG. 14 is a diagram illustrating tracking, multiple blocks at a time, according to various arrangements.

FIG. 15 is a schematic diagram illustrating an example read threshold estimator, according to various arrangements.

FIG. 16 is a diagram illustrating an example method for performing a read operation with sequential tracking HW stage, according to various arrangements.

FIG. 17 is a block diagram illustrating an example tracking HW structure in a controller, according to various arrangements.

FIG. 18 is a diagram illustrating an example method for performing a tracking procedure using the controller, according to various arrangements.

FIG. 19 is a diagram illustrating an example Deep Neural Network (DNN) for the tracking read thresholds estimation, according to various arrangements.

FIG. 20 is a diagram illustrating an example product code used to obtain suboptimal error vector under decoding failure, according to various arrangements.

FIG. 21 is a block diagram illustrating a non-volatile storage device, according to some arrangements.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

During NAND block life cycle, the NAND device may be affected by various types of physical phenomena based on the manner in which the NAND device is used. For example, Data Retention (DR) (e.g., storing of information for a specified period) may cause charge leakage over time and can be a dominant source of flash memory errors, mainly in higher lobes of a row voltage threshold distribution. In addition, Read Disturb (RD) refers to reading of a cell that causes nearby cells in a same memory block to change over time or to become programmed. A notorious effect of RD is erase lobe penetration which causes a significant increase of first threshold errors. The first threshold separates the erase lobe from the first lobe in a row voltage threshold distribution.

During device manufacturing, normal read thresholds per block of a non-volatile memory are defined. In the situation in which the block is under stress, these normal thresholds may no longer be adequate and may cause high Bit Error Rate (BER), and in turn, consequently causing decoding failures. Such failures may significantly degrade system performance since read retries must be executed. To mitigate the effects of stresses, such as DR and RD, the most adequate read thresholds should be determined and used in order to reduce the BER as much as possible. Determining the optimal read thresholds can include numerous read operations and may not be practical in actual non-volatile memory devices due to significant performance degradation impact. However, suboptimal thresholds can be determined using available data from a read operation and simple signal processing operations. Such suboptimal thresholds can significantly reduce BER as compared to normal thresholds. Sufficiently reducing the BER leads to reducing or avoiding decoding errors, thus improving system performance of the non-volatile memory device.

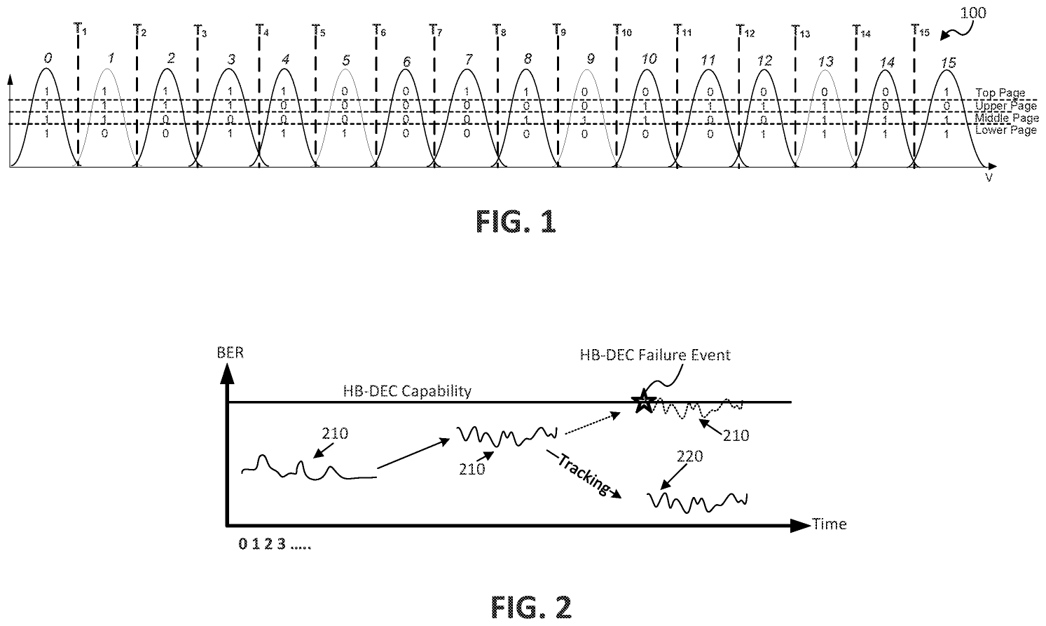

In a sequential read, an entire block is read page-by-page. This sequential read operation generates information that can be used to assess the block condition and determine most suitable read thresholds such that decoding failures can be avoided. In some implementations, once an entire target row is read and decoded successfully, the full read histogram and the error information per threshold from both right and left sides can be obtained. For a specific threshold, the number of errors depends on the intersection area between lobes separated by that threshold. The right hand side (r.h.s.) errors are the errors (e.g., erroneous read of voltage) located on the right side of the threshold along the voltage axis. The left hand side (l.h.s.) errors are the errors (e.g., erroneous read of voltage) located on the left side of the threshold along the voltage axis. The voltage axis increases in voltage from the left side to the right side as shown in FIG. 1. The read data and directional FBC information can be saved in buffers and can be used to accurately estimate the optimal thresholds of the target row. The number of buffers used and buffer size can be determined based on NAND memory constraints. In some examples, a tradeoff between the total buffer size and the read thresholds estimation accuracy is considered. Once the optimal thresholds of the target row are estimated accurately, the block condition can be assessed and more accurate read thresholds for the entire block can be obtained. For example, the block read thresholds can belong to a specific index of a predefined History Table (HT) saved in the controller. Given accurate read thresholds for a target row obtained after applying tracking, the block read thresholds can be updated by selecting a more appropriate HT index for the block. The new HT index read thresholds can be closer to the target row estimated read thresholds under some metric as compared to the block previous HT index read thresholds.

In sequential read, a large chunk of data is read in the same order as that in which the large chunk of data was programmed. Therefore, data is extracted from consecutive pages and rows of a block (e.g., a NAND block) of a non-volatile memory. The data is read and decoded in small portions. For example, decoding can be performed in a unit of 4 KB codeword (CW) from a 16 KB row. Each successful read operation generates information that can be used to assess the NAND block condition and to better estimate the read thresholds of next CWs, in case that the future CWs on same block have the same or similar stress. Thus, decoding failures of following CWs in the block can be reduced or prevented.

This arrangements described herein can provide low complexity methods for sequential read tracking that use the read and decoding results to estimate the best read thresholds for a target block based on current block conditions. A block can be fresh or suffer from Read Disturb (RD), Data Retention (DR), and so on. By efficiently identifying the target block stress condition, properly adjusting its read thresholds, using the information that already exists without additional read commands, many Hard Bit (HB) Decoding (HB-DEC) errors can be avoided, and system performance can be significantly improved in terms of read latency and throughput.

In some examples, the Failed Bit Count (FBC) is an actual number of errors per given number of row cells read. The number of cells can be the entire page size (e.g., of a page) or a part but not all of the page size (e.g., a portion of a page). FBC is used in some cases as performance metric instead of BER, which is the ratio between the FBC and the number of row cells read. In some examples, the information on a number of errors for at least a portion of a page includes the directional FBC information.

In some arrangements, for sequential reads in which after successful read operation of target row pages, the row read histogram can be obtained in addition to error information per threshold from both the right direction (e.g., r.h.s.) and left direction (e.g., l.h.s.). The error information is determined by comparing the decoder input with its output. In some arrangements, the target row read histogram and directional error information are used for accurately estimating the target row optimal read thresholds during sequential read transaction. Once accurate read thresholds of a target row are available, the accuracy of read thresholds for the entire block can be improved, given that all the rows of the block usually experience the same or similar stress. The relevant signal processing operations can be implemented on a NAND memory controller Hardware (HW) and/or Firmware (FW), and lends itself to low complexity processing.

FIG. 1 is a graph illustrating example histograms 100 of Voltage Threshold (VT) distribution, according to various arrangements. The VT distribution is for a 4 bits per cell (bpc) non-volatile memory device (e.g., flash memory device), e.g., a Quadruple level cells (QLC) with 16 lobes, denoted as 0-15. The depicted 16 lobes (distributions or histograms) corresponding to the 16 different bit combinations of four bits represented by the charge state of the cell. A lower page read uses thresholds T1, T3, T6 and T12 to separate the histograms 100 into those with Least Significant Bits (LSBs) of 0 into those of LSBs of 1. Read thresholds T2, T8, T11, and T13 are used to separate the histograms 100 into those with LSBs of 0 and those with LSBs of 1 for reading middle pages. Read thresholds T4, T10, and T14 are used to separate the histograms 100 into those with LSBs of 0 and those with LSBs of 1 for reading upper pages. Read thresholds T5, T7,T9, and T15 are used to separate the histograms 100 into those with LSBs of 0 and those with LSBs of 1 for reading top pages. The lower most lobe (denoted as 0) is known as the erase level.

During sequential read in which multiple pages of the same block are read and decoded, information that can be used to optimize read thresholds of target block. In blocks with high BER, updating the block read thresholds online can be useful in avoiding decoding failures and Read Retry (RR) events in the same sequential read and in future reads from this block. FIG. 2 is a graph illustrating example stress increase over time. In FIG. 2, the stress increase (e.g., due to DR) for a block is measured using BER (vertical axis) against time (horizontal axis). For example, the BER 210 is the BER for using default read thresholds, which is shown to increase over time. As shown, if tracking is not employed, at some point, the block BER violates the HB-DEC capability constraint due to the increasing stress, and HB-DEC failure can result. In contrast, if tracking is used, the block BER can be reduced (e.g., to the BER 220) before the HB-DEC capability violation to reduce the number of future RR events in this target block.

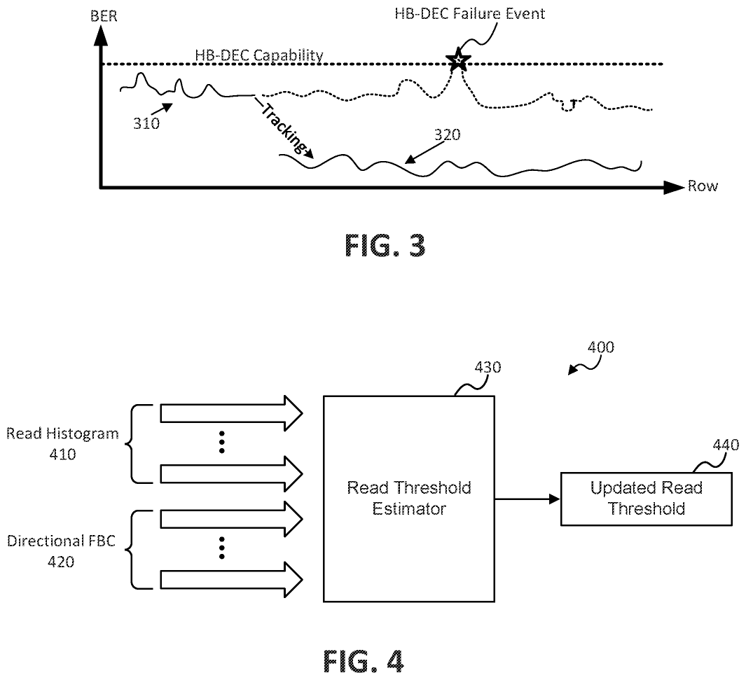

FIG. 3 is a graph illustrating example block marginal BER versus row number, according to various arrangements. In FIG. 3, reads and decoding are performed within the same block (e.g., row by row), in case of high stress (e.g., high BER and the HB-DEC capability is marginal). The X axis is the row number. The block is read sequentially, and given that the BER is high, HB-DEC failure event can be reached in one row. If tracking mechanism is invoked, the read thresholds can be updated before the potential HB-DEC failure event is reached, thus preventing the same. Based on the decoding results, the block has marginal BER 310, which is close to HB-DEC capability. Consequently, the next reads from the target block may result in decoding failures. Applying tracking in this case, the new BER 320 is low, and tracking can prevent RR event within the current sequential read transaction.

Some arrangements relate to sequential read tracking methods, which can be implemented using Hardware (HW). The sequential read tracking methods are simple, have low computational complexity, and are easy to integrate in read flows. The sequential read tracking methods use a small number of data buffers for saving relevant data and generating the read thresholds estimator input features. The sequential read tracking methods are suitable for any generation of NAND devices and do not depend on the NAND flash storage density. Although the arrangements of the sequential read tracking methods are described with respect to a QLC setup, the sequential read tracking methods can be likewise implemented for other storage density setup.

FIG. 4 is a schematic diagram illustrating an example read threshold estimator 430, according to various arrangements. The read threshold estimator 430 can be included or implemented in a controller of a non-volatile memory device, in some examples. The read threshold estimator 430 receives input features such as the read histogram 410 and the directional FBC 420. In some examples, the read histogram 410 is determined for read thresholds of lower, middle, upper, and top pages of a target row. The read histogram 410 can yield a plurality of input features (e.g., 16 input features, for the 15 read thresholds used in FIG. 1). In some examples, the directional FBC 420 includes per-threshold directional errors for each read threshold (e.g., in FIG. 1), where the errors can be for r.h.s. and l.h.s., for a total of 15×2 features. The directional FBC 420 can be inserted as actual values or as a result of in various formulation of the actual values, e.g., the log of the ratio between r.h.s. and l.h.s. errors. In some examples, the 15 read thresholds values used on the target row can be used as input features to the read threshold estimator 430. In some examples, Meta Data (MD) such as cycle count, row index, and so on can be used as input features to the read threshold estimator 430. The output of the read threshold estimator 430 includes an updated read threshold 440.

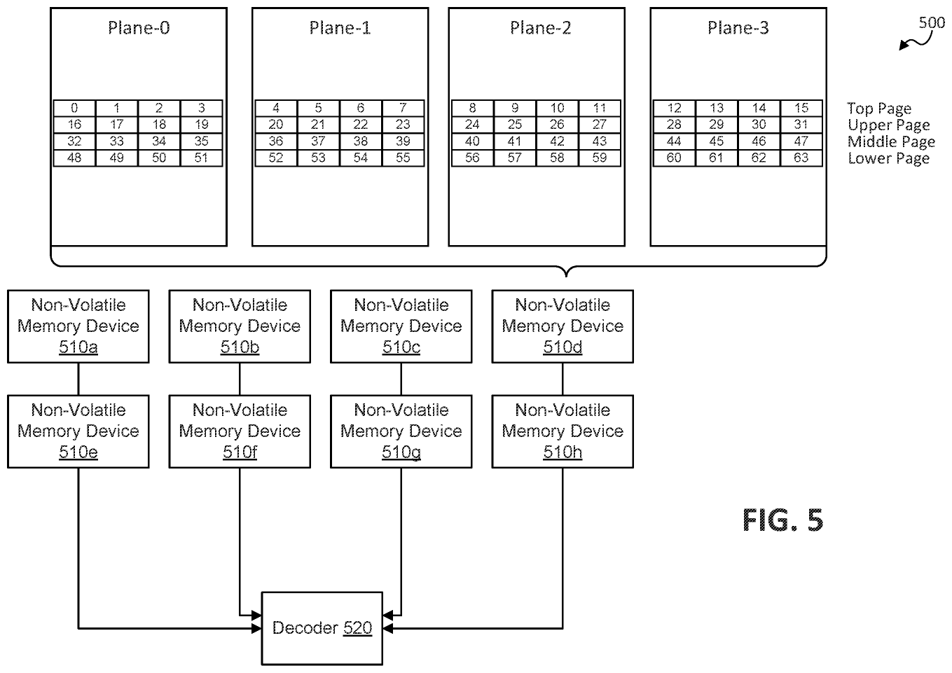

FIG. 5 is a diagram illustrating example system read of a target row across multiple non-volatile memory devices of a system 500, according to various arrangements. The system 500 includes non-volatile memory devices 510a, 510b, 510c, 510d, 510e, 510g, 510g, and 510h. A sequential tracking operation includes reading all pages of a target row (whose size is for example 16 KB cells) or a target CW. In some examples, a row includes a plurality (e.g., 4) CWs, e.g., 4 KB per CW. In actual systems, in sequential read, a specific row or CW is usually not read page by page. In order to increase throughput, read of a specific page (e.g., lower page) is performed from multiple planes and multiple devices in parallel. In FIG. 5, the non-volatile memory of each of the non-volatile memory devices 510a-510h has 8 dies (e.g., chips), 4 planes (e.g., 4 different blocks), 4 pages per row, and 4 CWs per page. Each CW is denoted using a reference numeral 0-63. A single row read over all dies of the non-volatile memory devices 510a, 510b, 510c, 510d, 510e, 510f, 510g, and 510h reads (8 dies)×(4 planes)×(16KB page)×(4 pages)=2 MB of data. The read data can be provided to a decoder 520 for decoding.

In some arrangements, buffering methods can be used to obtain the read histogram needed for the read thresholds estimator 430 to perform tracking. In order to buffer the data needed for read histogram generation (e.g., for 4 KB CWs), one of two methods can be used.

In a first method, all 32 blocks (8 dies × 4 planes system) are tracked simultaneously at a same time. In this case, all the data (2 MB, or 512 KB if 4 KB CWs are buffered per page) is buffered. Then, tracking for all the blocks is performed in the sequential read transaction. This method can quickly prevent decoding failures in many blocks.

In a second method, tracking on one block is performed one at a time. In this method, all 32 blocks are read, and data is buffered only for a specific block at a time. Tracking is performed for one block at a time. Thus, tracking update for a single block can be performed during a 2 MB sequential read transaction. Tracking updates for all 32 blocks can be performed during a 64 MB sequential read transaction (due to the sequential read order). The requirement of the memory (e.g., Static Random-Access Memory (SRAM)) of the controller for the second method is less than that of the first method. The first and second methods present tradeoff between SRAM requirements (e.g., the required buffer size for tracking during a single sequential read transaction) and tracking frequency (e.g., the number of blocks tracked during a single sequential read transaction). In some examples, a combination of the first and second methods can be used.

In some implementations, the read threshold estimator 430 uses two input feature types including the read histogram 410 (e.g., 16 features) and the number of directional errors per threshold (e.g., (2 directions)×(15 thresholds)=30 features). For a specific row with N+1 cells, the data is buffered to generate these two input features. In some arrangements, the tracking methods can include one of two buffering methods from which the input features for the tracking read thresholds estimator can be obtained.

In a first buffering method, while reading and decoding during sequential read transaction, 4 read-data buffers based on all page types are used to buffer the original read data before decoding, and 4 fixed-data buffers based on all page types are used after decoding (where the data is fixed). Then, 8-bit histogram is performed on the buffers for the original read data and the fixed read data. From the 8-bit histogram, the 16 read histogram features and 30 directional errors per threshold features can be directly extracted. Thus, in some examples, the total HW budget is typically 8 buffers with 256 optional results.

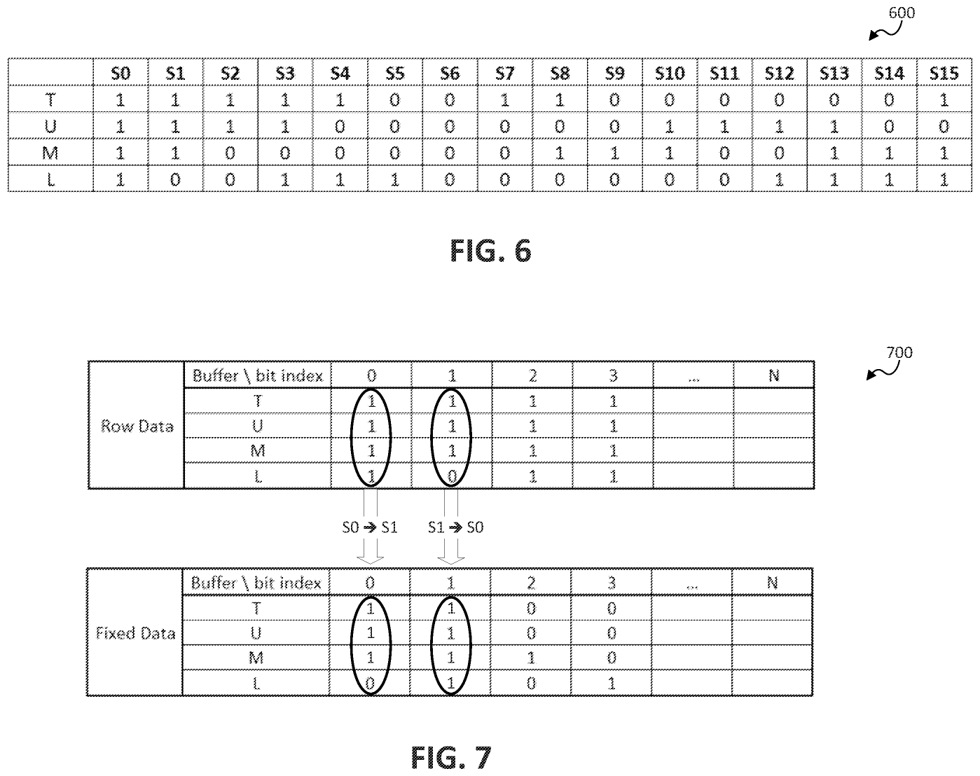

FIG. 6 is a table illustrating state information represented in buffers (e.g., 4 buffers) by reading multiple (e.g., 4) page types according to the mapping in FIG. 1, according to various arrangements. Each buffer corresponds to a page type. The page types include the top page (T), the upper page (U), the middle page (M), and the lower page (L). The 4 data buffers containing original read data before decoding and are used to obtain the 16 features of the read histogram 410, e.g., a number of cells that belong to S0, number of cells that belong to S1, . . . , number of cells that belong to S15 for each page type.

FIG. 7 illustrates extracting directional error information by comparing 4 pre-decode data buffers with 4 post-decode data buffers, according to various arrangements. The row data refers to original read data or pre-decode data. Each buffer of the row data corresponds to a page type. The fixed data refers to the row data that has been fixed by decoding. Each buffer of the fixed data corresponds to a page type. In some examples, bit index of 0 (e.g., bit [0]) (row contains N+1 bits) is changed from state “0” (S0) to state “1” (S1) after decoding. S0 and S1 are shown in FIG. 6. In FIG. 7, S0 “1111” is moved to S1 “1110” for bit [0] and S1 “1110” is moved to S0 “1111” for bit [1]. Thus, an error on the first threshold from left to right occurred (l.h.s. error) for bit [0] and can be counted for T1. Additionally, bit [1] is changed from S1 to S0 after decoding. Thus, an error on the first threshold from right to left occurred (r.h.s. error) for bit [1] and can be counted for T1.

For most corrected errors, state X changes to a neighboring state, e.g., state X+1 or state X−1. Under some circumstances, unexpectable errors can occur in which state X is corrected to state Y, where the difference between X and Y is greater than 1 (e.g., |X−Y|>1). Such errors (e.g., correcting state 3 to state 0) can occur, for example, in high RD with significant erase penetration. Such error is r.h.s. error for T1 and is properly handled using the first buffering method. Consequently, from the 8 data buffers an 8-bit histogram with 256 optional results can be created (using histogram engines). The 16 read histogram features and the 30 directional error features can be extracted to be applied as input features to the read threshold estimator 430.

A second buffering method can be applied in case of high probability of a single error existing in a given bit-index on all pages, given that most errors occur between neighboring states. In the second buffering method, the number of buffers used can be reduced as compared to the first buffering method.

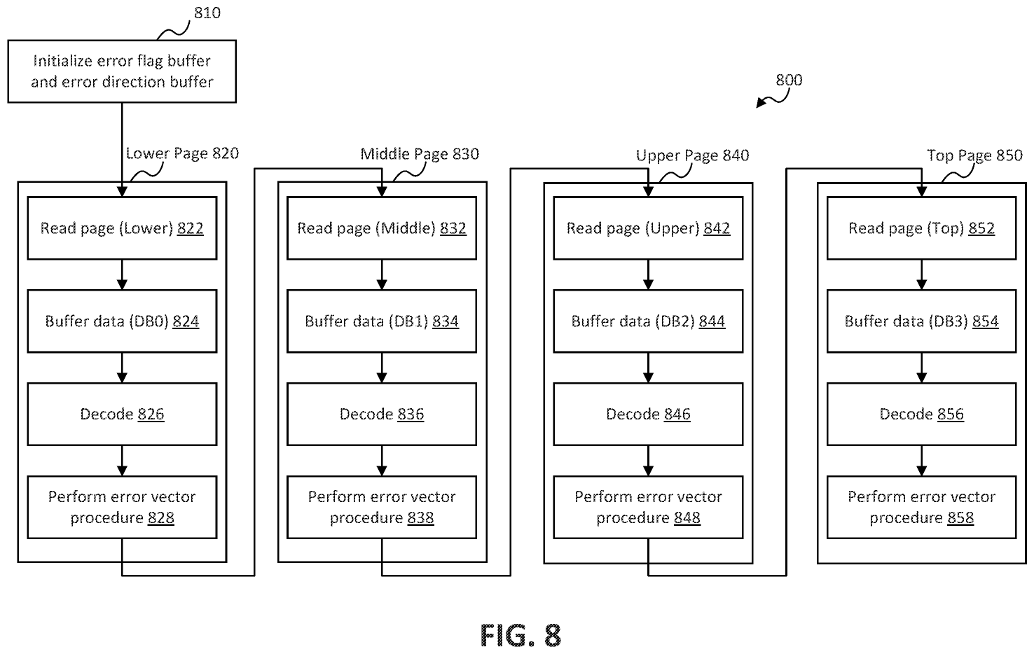

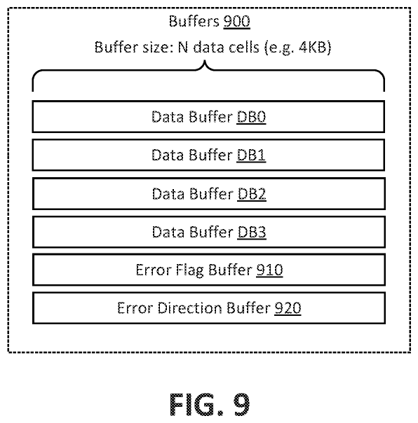

FIG. 8 is a flowchart diagram illustrating an example second buffer method 800, according to various arrangements. FIG. 9 is a diagram illustrating example buffers 900 used in the method 800, according to various arrangements. The method 800 can be implemented using the controller of the non-volatile memory device. The buffers 900 can include at least one memory device of the controller. The buffers 900 include data buffers DB0, DB1, DB2, and DB3. In the second buffer method 800, while reading and decoding, 4 read buffers (e.g., data buffers DB0, DB1, DB2, and DB3) for the read result per cell before decoding the original read data (e.g., the raw data) are used. The buffers DB0, DB1, DB2, and DB3 are used for reading of all pages of the target row. The decoding in 826, 836, 846, 856 generates several outputs in addition to the fixed data and one of the decoding outputs may be a Decoder Error Vector of size N+1 that indicates on error for bit “k”, k=0, . . . , N, in the original data. Decoder Error Vector [k]=‘1’ if an error exists in bit “k” of the original data and Decoder Error Vector [k]=‘0’ if an error does not exist in bit “k” of the original data. The buffers also include additional buffers that are initialized to zeros (before usage) to indicate whether an error exists for the given cell (e.g., the error flag buffer 910) and its direction. The direction can include a 0→1 error (e.g., a zero to one error) or a 1→0 error (e.g., a one to zero error). In some examples, a 0→1 error refers to a bit in the data buffer was read as “0” and indicated as an error in the Decoder Error Vector and a 1→0 error refers to a bit in the data buffer was read as “1” and indicated as an error in the Decoder Error Vector (e.g., the error direction buffer 920). In some examples, the number of r.h.s. and l.h.s. errors per threshold can be extracted from the 6-bit histogram result and saved in a suitable memory of the controller that may be FW memory or HW memory. At 810, the error flag buffer 910 and the error direction buffer 920 are initialized to zeros.

For the lower page 820, at 822, the lower page 820 is read. At 824, the original read (raw) data is buffered in data buffer DB0. At 826, the original read data is decoded to fix the original read data, and one of the decoding outputs may be a Decoder Error Vector. At 828, error vector procedure is performed using the buffered data in DB0 824 and the Decoder Error Vector to update the Error Flag Buffer 910 and the Error Direction Buffer 920. For the middle page 830, at 832, the middle page 830 is read. At 834, the original read (raw) data is buffered in data buffer DB1. At 836, the original read data is decoded to fix the original read data, and one of the decoding outputs may be a Decoder Error Vector. At 838, error vector procedure is performed using the buffered data in DB1 834 and the Decoder Error Vector to update the Error Flag Buffer 910 and the Error Direction Buffer 920. For the upper page 840, at 842, the upper page 840 is read. At 844, the original read (raw) data is buffered in data buffer DB2. At 846, the original read data is decoded to fix the original read data, and one of the decoding outputs may be a Decoder Error Vector. At 848, error vector procedure is performed using the buffered data in DB2 844 and the “Decoder Error Vector” to update the Error Flag Buffer 910 and the Error Direction Buffer 920. For the top page 850, at 852, the top page 850 is read. At 854, the original read (raw) data is buffered in data buffer DB3. At 856, the original read data is decoded to fix the original read data, and one of the decoding outputs may be a “Decoder Error Vector”. At 858, error vector procedure is performed using the buffered data in DB3 854 and the “Decoder Error Vector” to update the Error Flag Buffer 910 and the Error Direction Buffer 920. In some examples, the reading at 822, 832, 842, and 852 uses an initial voltage threshold (e.g., a first voltage threshold). The updated or estimated voltage threshold, such as the output of the read threshold estimator 430 or 1530, is referred to as a second voltage threshold.

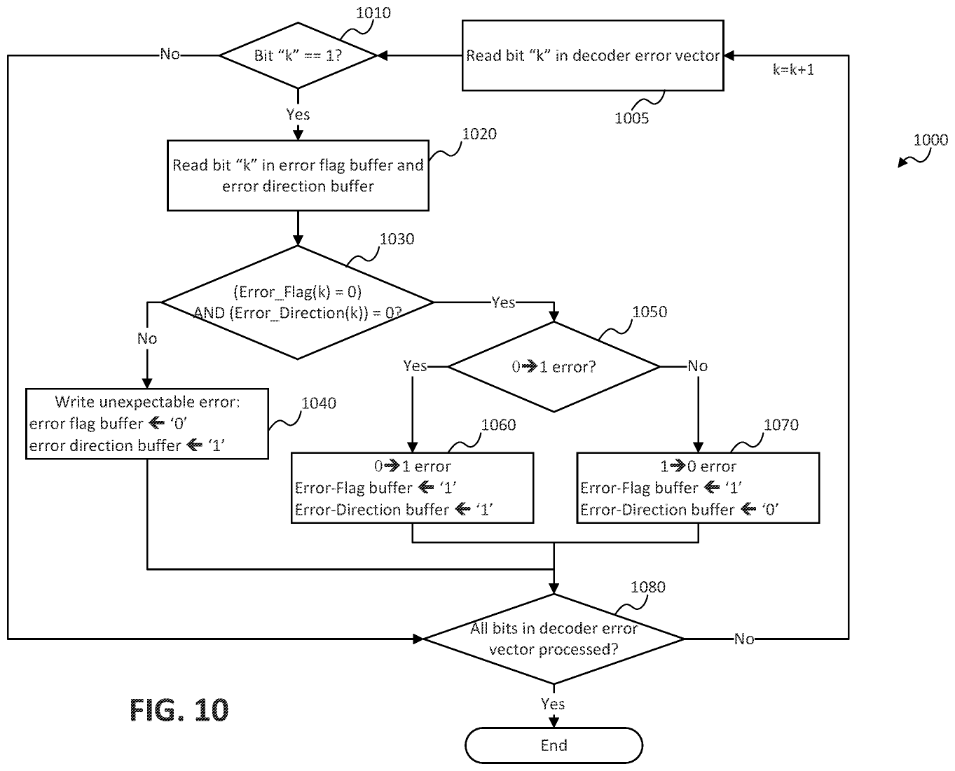

FIG. 10 is a flowchart diagram illustrating an example method 1000 for writing the error flag buffer 910 and the error direction buffer 920 for the second buffering method 800, according to various arrangements. The method 1000 can be implemented using the controller of the non-volatile memory device. The method 1000 is an example of the error vector procedure performed at 828, 838, 848, and 858. The method 1000 can be performed for each error in the decoder error vector. The bits determined by the ECC to be with no error are skipped at 1010. The kth bit that is indicated to be with an error in the decoder error vector is examined in the error vector procedure. At 1005, information for the bit “k” is read in the decoder error vector, where “k” is the bit position in the decoder error vector. The decoder error vector stores information for bits 0 to N, where k is one of the bits 0 to N. The decoder error vector stores output from the decoding 826, 836, 846, and 856. At 1010, the controller determines whether the bit “k” is 1, e.g., whether there is an error corresponding to bit “k” in the original data. In response to determining that the bit “k” is not 1 (e.g., no error), the method 1000 moves to 1080. In response to determining that the bit “k” is 1 (e.g., there is an error), the method 1000 moves to 1020. At 1020, information for bit “k” is read in the error flag buffer 910 and error direction buffer 920. In particular, the state of the error flag buffer 910 and the state of the error direction buffer 920 are read from the buffers 910 and 920, respectively. For example, whether the error exists for bit “k” and the direction of the error are read from the buffers 910 and 920, respectively. In some examples, “k” refers to an index of the current error in the decoder error vector. At 1030, the error flag for “k” is checked to see if it equals to “0” and the error direction for “k” is checked to determine if it equals to “0”. In response to determining that both the error flag for “k” and the error direction for “k” are equal to “0”, then the error direction (e.g., 0→1 or 1→0) is checked based on the decoder error vector and the read buffer at 1050. In response to determining that the error direction is 0→1, the error flag buffer 910 is set to “1” and the error direction buffer 920 to “1” in 1060. In response to determining that the error direction is 1→0, the error flag buffer 910 is set to “1” and the error direction buffer 920 is set to “0” in 1070. In response to determining that the error flag for “k” equals to “1” and/or the error direction for “k” equals to “1” at 1030, unexpectable error is written at 1040, including setting the error flag buffer to “0” and setting the error direction buffer to “1”.

At 1080, it is determined whether all bits of the N+1 bits of the decoder error vector have run through the method 1000, e.g., whether k is equal to N. In response to determining that not all bits in the decoder error vector have run through the method 1000, the method 1000 returns to 1005 for an error with the next index (e.g., setting k to be k+1). On the other hand, in response to determining that all bits in the decoder error vector have run through the method 1000, the method 1000 ends. In some examples, some of the bits in the decoder error vector have been found by the ECC to include an error. With high probability, this bit error belongs to an adjacent state, e.g., S1 fixed by the decoder to be S0. In this case, this bit is detected as an error in the decoder error vector for only a single page. With low probability, this bit error belongs to a nonadjacent state, e.g., S2 fixed by the decoder to be S0. In this case, this bit is detected as an error in the decoder error vector for more than a single page. In 1030, a page error is checked to see if it was previously detected for an examined bit. For example, lower page error was detected to the examined bit and afterwards, a middle page error was detected as well. If error flag=0 and error direction=0, this is the first page error of the examined bit (cell in the flash). Then, it is determined whether this error is a 0→1 error or a 1→0 error. If the expression (error flag=0 AND error direction=0) is false, there is an unexpectable error for the examined bit.

In case that a data cell is detected with bit error due to nonadjacent state, e.g., S2 fixed by the decoder to be S0, an error can be found on same data cell in more than a single page. Therefore, when the second error is observed, the “error flag” is already set. In that case, the value of an unexpectable error is set to be “0” for the error flag buffer and “1” for the error direction buffer. This buffer update can include ReadModifyWrite operation, given that the data needs to be read and checked first to determine if an error already occurred in this data cell. In rare cases, a data cell is detected with bit error due to nonadjacent state but only single page error is found, e.g., S3 fixed by the decoder to be S0. Such cases are not recognized as unexpectable errors using the second buffer method 800.

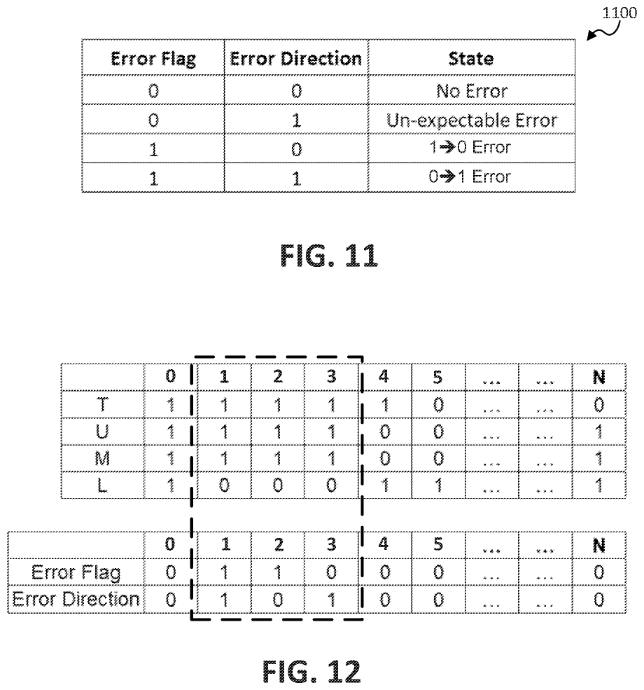

By using histogram engines on the raw data buffers and accumulated error flag buffer 910 and error direction buffer 920, a 6-bit histogram can be generated. From the 6-bit histogram with 64 possible values, the 16 read histogram features and the 30 values of errors from each direction per threshold are extracted. In some examples, the total number of unexpectable errors can be monitored and used as an indication to high stress or hard errors. If such indication is activated, the controller can determine to refresh the target block based on this information. FIG. 11 is a table illustrating an example write policy per data cell for the error flag buffer 910 and error direction buffer 920, according to various arrangements. For example, the error flag “0” and the error direction “0” indicates a state of no error. The error flag “0” and the error direction “1” indicates a state of unexpectable error. The error flag “1” and the error direction “0” indicates an 1>0 error. The error flag “1” and the error direction “1” indicates a 0→1 error.

FIG. 12 is a table illustrating an example second buffer method (e.g., the second buffering method 800), according to various arrangements. In some examples, for the second buffer method, 6 buffer values per row cell (row includes N+1 data cells) are shown in FIG. 12. In this example, in data cell 1 the 6 bits referring to this cell represent a r.h.s. error associated with T1. In data cell 2 the 6 bits referring to this cell represent a l.h.s. error associated with T2. In data cell 3, there is an unexpectable error, e.g., error that is not from an adjacent state.

The page size affects the tracking read thresholds estimation accuracy, given that the more data available (higher page size) for histogram generation (e.g., 8-bit histogram in the first buffering method, 6-bit histogram in the second buffering method), the higher the accuracy of the estimator 430. Smaller page size can increase the tracking rate given that tracking can be performed on more blocks during a single row sequential tracking transaction. Thus, for a given system with a given buffer size, the page size per tracked block is set such that the tradeoff between tracking rate and estimator accuracy is balanced properly in accordance with the specific application. This tradeoff can also be changed in an application along its life cycle. In some examples the second buffering method with six 4 KB buffers and the system implementation of FIG. 5 are used. In such examples, a single row read over all dies includes reading 2 MB of data.

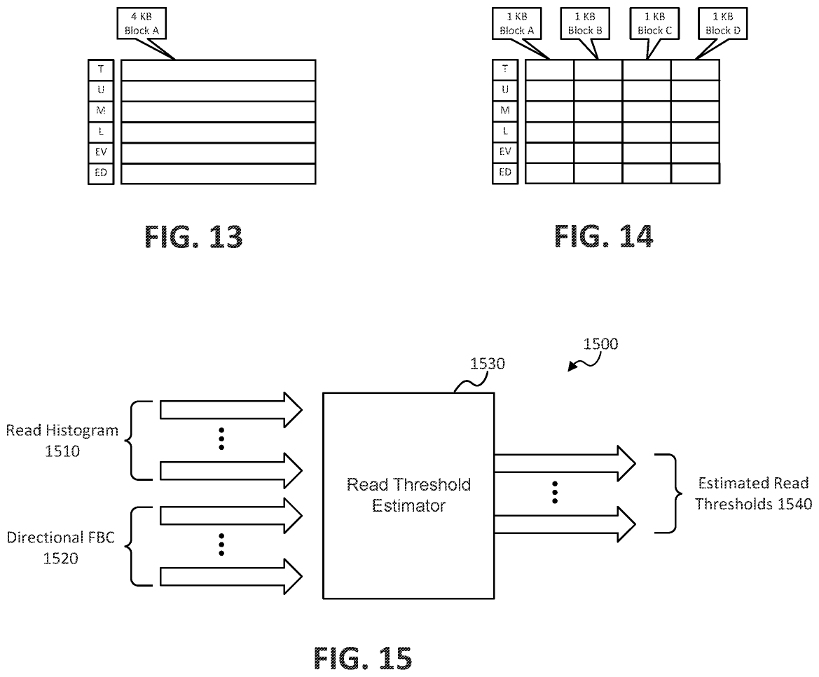

FIG. 13 is a diagram illustrating tracking, one block at a time, according to various arrangements. In FIG. 13, T stands for the top page buffer, U stands for the upper page buffer, M stands for the middle page buffer, L stands for the lower page buffer, EV stands for the error vector buffer, and ED stands for the error direction buffer. In FIG. 13, 4 KB target row cells from one block is tracked at a time. In this case, only one block is updated during a 2 MB read transaction. Thus, the page size per block is 4 KB. The highest estimation accuracy can be obtained given the available buffer size of 4 KB.

FIG. 14 is a diagram illustrating tracking, multiple blocks (e.g., 4 blocks) at a time, according to various arrangements. In FIG. 14, T stands for the top page buffer, U stands for the upper page buffer, M stands for the middle page buffer, L stands for the lower page buffer, EV stands for the error vector buffer, and ED stands for the error direction buffer. In FIG. 14, 1 KB pages from 4 blocks (e.g., Block A, Block B, Block C, and Block D) are tracked at a time. Thus, 4 blocks are updated during a 2 MB read transaction. In this case, although the estimation accuracy can degrade compared to Error! Reference source not found. implementation of FIG. 13, the tracking rate is 4 times faster.

In some examples, the sequential read tracking method estimates read thresholds of a target block in connection with or during a sequential read. FIG. 15 is a schematic diagram illustrating an example read threshold estimator 1530, according to various arrangements. The read threshold estimator 1530 of a sequential tracking input/output structure can be included or implemented in a controller of a non-volatile memory device, in some examples. The read threshold estimator 1530 receives input features such as the read histogram 1510 and the directional FBC 1520. In some examples, the read histogram 1510 is determined for read thresholds of lower, middle, upper, and top pages of a target row. The read histogram 1510 can yield a plurality of input features (e.g., 16 input features, for the 15 read thresholds used in FIG. 1). In some examples, the read histogram 1510 includes data for estimating the optimal read thresholds of a target row.

In some examples, the directional FBC 1520 includes per-threshold directional errors for each read threshold (e.g., in FIG. 1), where the errors can be for r.h.s. and l.h.s., for a total of 15×2 features. The directional FBC 1520 can be inserted as actual values or as a result of in various formulation of the actual values, e.g., the log of the ratio between r.h.s. and l.h.s. errors. In some examples, the 15 read thresholds values used on the target row can be used as input features to the read threshold estimator 1530. In some examples, MD such as cycle count, row index, and so on can be used as input features to the read threshold estimator 1530. The output of the read threshold estimator 1530 includes, e.g. 15, estimated read thresholds 1540.

The estimated read thresholds 1540 are used for block read thresholds update. The block update can be performed with minimal latency in order to prevent performance degradation. At or soon after the start-of-life of a non-volatile memory device, the tracking process may become a bottle-neck given that block optimal read thresholds may not change significantly compared to this block normal thresholds. The tracking block can also include a classification stage in which the resulting estimated thresholds are classified (e.g., by a classifier included in or coupled to the estimator) to a certain codebook index, history table index, or shift index, which points to a pre-defined set of a number (e.g., 15) of thresholds. This pre-defined thresholds set belongs to a finite set of codebook indices. The chosen codebook index is set and used for future reads from the target block, for example, as a default index or the index to be applied for a read transaction without shifting to another index for the same transaction. In some examples, the tracking estimated read thresholds can be quantized and classified to best match a target block outside the tracking block.

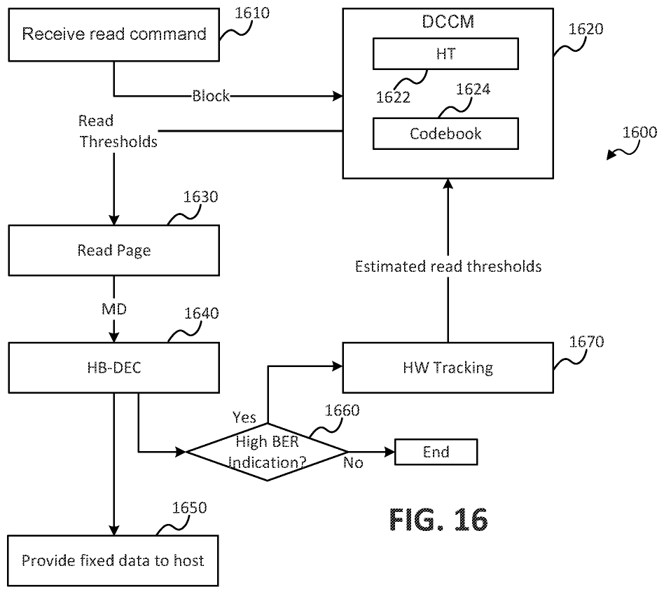

FIG. 16 is a diagram illustrating an example method 1600 for performing a read operation with sequential tracking HW stage, according to various arrangements. The method 1600 can be performed by the controller of a non-volatile memory using HW. The controller further includes the Data Closely Coupled Memory (DCCM) 1620, which can be a database implemented using any suitable memory in the controller. The controller contains (e.g., stores in a suitable memory such as the DCCM 1620) an HT 1622 of predefined read thresholds (identified by indices) and a codebook 1624 that includes an index per block that specifies which read thresholds (e.g., default read thresholds) from the HT 1622 should be used when reading this block.

At 1610, the controller receives a read command from a host over a suitable host interface. Although in 1610, read command (e.g., a functional read) from the host is used as an example, the read operation can also be a background or control-like read operation, or a read operation during a garbage collection process. The read operation includes reading data located on a specific block (e.g., on a specific block of a chip) of the non-volatile memory. In response, the controller retrieves the current read thresholds for the block from the HT 1622 and the 1624 by performing for example an HT GET operation. For example, the HT 1622 includes predefined read thresholds identified by indices, and the codebook 1624 includes an index of those indices for the block to be used for reading data on the block. Therefore, the HT GET is performed to extract the current read thresholds of the block based on the block current codebook index.

At 1630, using the block read thresholds (e.g., the initial or first read thresholds), a page read is performed on a page of the block and HB-DEC is executed at 1640. The MD for the block can be determined as a result of reading the page at 1630. In the examples in which HB-DEC is successful, the FBC information can be obtained. The controller can fix the data using any suitable ECC. At 1650, the controller provides the fixed data back to the host in response to the read command, over the host interface. In some examples, at 1660, it is determined whether the BER is greater than a predefined BER threshold. That is, a high-BER indication is implemented in case that the number of errors is greater than the predefined BER threshold. In response to determining that the BER is greater than the BER threshold, tracking is performed on the target block at 1670 to determine the estimated read thresholds or updated read thresholds (e.g., the second read threshold) in the manner described. Otherwise, in response to determining that BER is less than the BER threshold, tracking is less relevant given that current block thresholds are sufficiently accurate, and the method 1600 ends.

In HW tracking 1670 using the read threshold estimator 430 or 1530, all the relevant information is saved into the buffers during the sequential read transaction in the manner described. For example, the input features such as read histograms 410 or 1510, the directional FBC 420 and 1520, and so on can be generated. The read threshold estimator 430 or 1530 can estimate the target row optimal read thresholds based on such input features in the manner described. Using the estimated read thresholds that appear in the tracking stage output, the target block codebook index is updated such that the index for the block points to read thresholds within the HT that are closest (under some metric) to the tracking output read thresholds. For example, an HT SET operation can be performed to update the codebook index. Generally, HT-GET and HT-SET operations can be implemented in HW or FW simultaneous to read flow.

In some arrangements, blocks are programmed roughly at the same time. Typically, sequential read transactions are performed on such blocks. Thus, all blocks that are associated with the same sequential read transaction may have similar stress. Consequently, once tracking on one block is completed, the codebook indices of all blocks (e.g., including at least one additional block) associated with (e.g., programmed at the same time as) this block are updated in a similar manner without additional tracking on them.

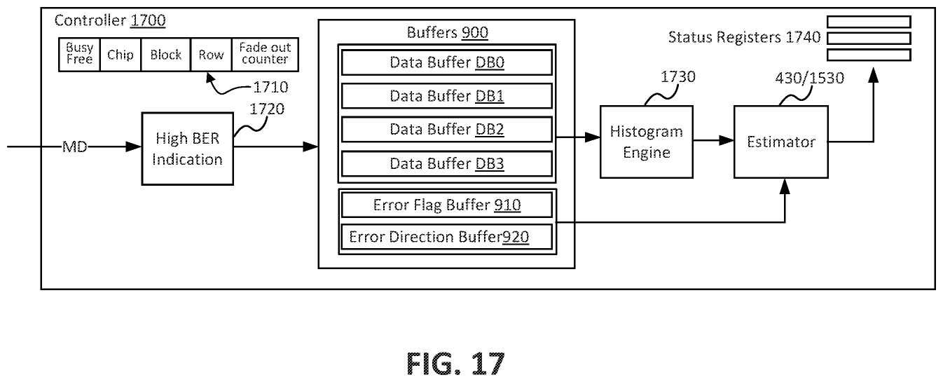

FIG. 17 is a block diagram illustrating an example tracking HW structure in a controller 1700, according to various arrangements. The controller 1700 includes a control-set register 1710 used to identify the block that is being tracked and indicate various aspects of the block. In some examples in which high BER indication occurs for specific block at 1720 (based on MD), specific chip, and specific row, the control-set register 1710 is set to “busy” (assuming it was free), and the chip number, block number, and row number are configured accordingly. The chip number, block number, and row number are considered as the MD used to determine whether the BER is above the threshold. The data is accumulated in 6 buffers DB0, DB1, DB2, DB3, 910, and 920 as described relative to FIG. 9 (for the second buffering method) when the pages of the block that is being tracked arrive to the decoder. The fadeout counter can be used if the amount of time needed to accumulate the data exceeds a threshold and the block tracking operation is canceled, e.g., due to decoding failures that need to be handled urgently. A histogram engine 1730 generates the input features, e.g., the 16-bin read histogram and 15×2 directional errors, from the accumulated data. Then, read thresholds estimator 430/1530 is applied and the estimated read thresholds are saved in status register 1740. HT SET operations can be performed according to the data in the status registers 1740.

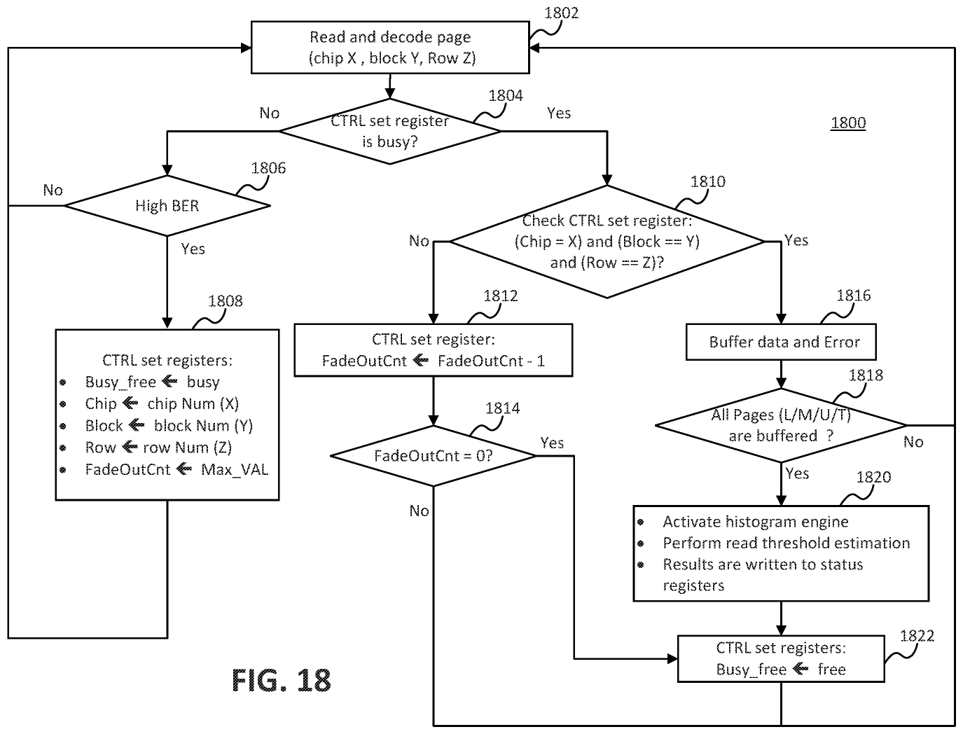

FIG. 18 is a diagram illustrating an example method 1800 for performing a tracking procedure, according to various arrangements. The method 1800 can be performed by a controller of a non-volatile memory such as the controller 1700. As data arrives to the decoder in a non-consecutive order (not page-after-page from the same block of a same non-volatile memory), the MD (e.g., chip number, block number, row number) can be followed and monitored, and once a page with a high BER is detected, the block MD information (chip number, block number, row number) is marked in control-set registers 1710, and buffer its data from all pages.

At 1802, the controller reads and decodes a page on chip X, block Y, and row Z. At 1804, the controller determines whether the control set register 1710 is set to be busy. In response to determining that the control set register 1710 is not busy, the controller determines whether the block has a high BER (e.g., the BER of the block exceeds a BER threshold) at 1806. In response to determining that the block does not have a high BER, the method 1800 returns to 1802. On the other hand, in response to determining that the block has a high BER, at 1808, the parameters of the control set register 1710 (busy_free) can be set as a busy state, the chip number to be X, the block number to be Y, the row number to be Z, and the fade out counter to be a maximum value. Thereafter, the method 1800 returns to 1802.

In response to determining that the control set register 1710 is busy, at 1810, the controller checks the control set register whether the chip is set to be chip number X, the block is set to be block number Y, and the row is set to be row number Z in the control set register. In response to determining at least one of the chip is not set to be chip number X, the block is not set to be block number Y, or the row is not set to be row number Z, at 1812, the controller set register sets the fade out count to be the current fade out count minus 1. At 1814, the controller determines whether the fade out count is 0. In response to determining that the fade out count is not 0, the method 1800 returns to 1802. In response to determining that the fade out count is 0 at 1822, the control set register is set to be free, and the method 1800 returns to 1802.

In response to determining that the chip is set to be chip number X, the block is set to be block number Y, and the row is set to be row number Z in the control set register, the controller buffers the data and the error in the manner described using the buffers 900, at 1816. At 1818, the controller determines whether all pages (e.g., lower, middle, upper, and top page types) are buffered. In response to determining that not all pages are buffered, the method 1800 returns to 1802. On the other hand, in response to determining that all pages are buffered, at 1820, the histogram engine is activated, the read threshold estimation is performed in the manner described, and the results are written to the status registers 1740. At 1822, the control set register is set to be free, and the method 1800 returns to 1802.

The sequential tracking methods described herein includes data buffering and histogram engines. In some arrangements, tracking methods with reduced latency are described. Fast sequential tracking can use only FBC from multiple pages to estimate improved read thresholds for the target block. Estimation accuracy may be reduced compared to the full sequential tracking. A faster approach includes using a single page FBC that may be noisy but can indicate if the block is under high stress, to determine improved read thresholds for the target block.

In some arrangements, decoding statistics per read command of same block can be saved (e.g., in a suitable memory of the controller or another memory external to the controller) during the sequential read operation and applied to recursive read thresholds update. The read threshold estimator 430 or 1530 takes into account all historical statistics of the target block and the current page read result. The historical statistics include the previous updated or estimated read threshold, which is a sufficient statistic, so the memory and computational complexity do not grow in time. Such recursive tracking may produce accurate read thresholds for the target block. The tracking methods described herein can be implemented using a Kalman-type filter that may be a Deep Neural Network (DNN) based (see e.g., G. Revach, N. Shlezinger, X. Ni, A. L. Escoriza, R. J. G. van Sloun and Y. C. Eldar, “KalmanNet: Neural Network Aided Kalman Filtering for Partially Known Dynamics,” in IEEE Transactions on Signal Processing, vol. 70, pp. 1532-1547, 2022, doi: 10.1109/TSP.2022.3158588). The target of this tracker can be either continuous refinement of read thresholds from a finite set or direct estimation of the optimal read thresholds. Accordingly, historical output read thresholds (e.g., second read thresholds) for the block are saved. The current second read threshold is determined based at least in part of the read histogram, the information on the number of the errors for at least the portion of the page, and the historical second read thresholds (and in some cases other inputs such as the current, first read threshold as described herein). The read threshold estimator can include or be implemented using a linear estimator, a Kalman-type filter or a DNN. Accordingly, at least one an estimator or classifier is deployed to determine the second read threshold. A function may be applied on the number of the errors as an input for the estimator/classifier.

In some arrangements, a method to estimate the read thresholds of a target row includes using a linear combination of the input features. That is, the updated read threshold can be determined based on a linear combination of the input features such as the read histogram, directional FBC, and so on. In some examples, 16 read histogram input features and 30 directional error input features (e.g., an overall 46 features) are used for a QLC setup. The controller can apply nonlinear transformations on the input features to allow the input features to be more linearly dependent and better fit a linear estimator. Thus, the number of input features for the estimation may be different from 46. For example, the QT has 16 input features obtained from the 15 mock reads. In some examples in which there are M input features, for the 15 thresholds estimation, the following estimation results \hat{V}_{15×1} for 15 read thresholds can be determined:

$${\hat{V}}_{15 x 1} = {X}_{15 x M} \cdot {H}_{M x 1} ,$$

where H_{M×1} is the vector of input features, and X_{15×M} is a linear estimator coefficients matrix, trained offline using a database.

The coefficient matrix, X, can be obtained using a simple linear regression. The read histogram input features and the directional error input features usually have very different distributions. Therefore, input normalization can be applied. Input normalization is a machine learning technique for improving training accuracy and reducing training time. Input normalization can include, for example, subtracting the mean value from each feature column and dividing by its standard deviation (std). After input normalization all input features have the same distribution in terms of mean (e.g., mean=0) and std (e.g., std=1).

The direct method to obtain the linear estimator coefficients matrix, X, is to use the least squares method to minimize the threshold estimator mean squared error for the linear fit. A function of the threshold FBC is used as metric. For example, the mean power 6 or 7 of the estimated threshold added BER is minimized rather than the threshold estimator mean squared error compared to the optimal threshold, to focus on avoiding outliers with exceptionally high added BER rather than simply the mean performance. Thus, iterative weighted least squares is used. First, the weights are initialized to equal values and normalized such that the sum of the weights is one. Then, a weighted least squares algorithm is iteratively applied to determined X, for each estimated threshold where the weights are some function of the estimated threshold added BER per row in the database. For example, the second power of the current estimated threshold added BER can be used as weights per database row for the following iteration. After each iteration, the performance under the chosen metric (e.g., mean power 6 of added BER) can be measured, and if there is improvement compared to previous iteration, the current linear estimator coefficients matrix X is saved. The maximal number of iterations is a hyperparameter of the optimization. In response to determining that the weights do not change between iterations, the optimization method can be stopped. Alternatively, the optimization of X is stopped once the maximal number of iterations is reached. The saved linear estimator coefficients matrix X from the iteration where the best performance in terms of the chosen metric was obtained is used.

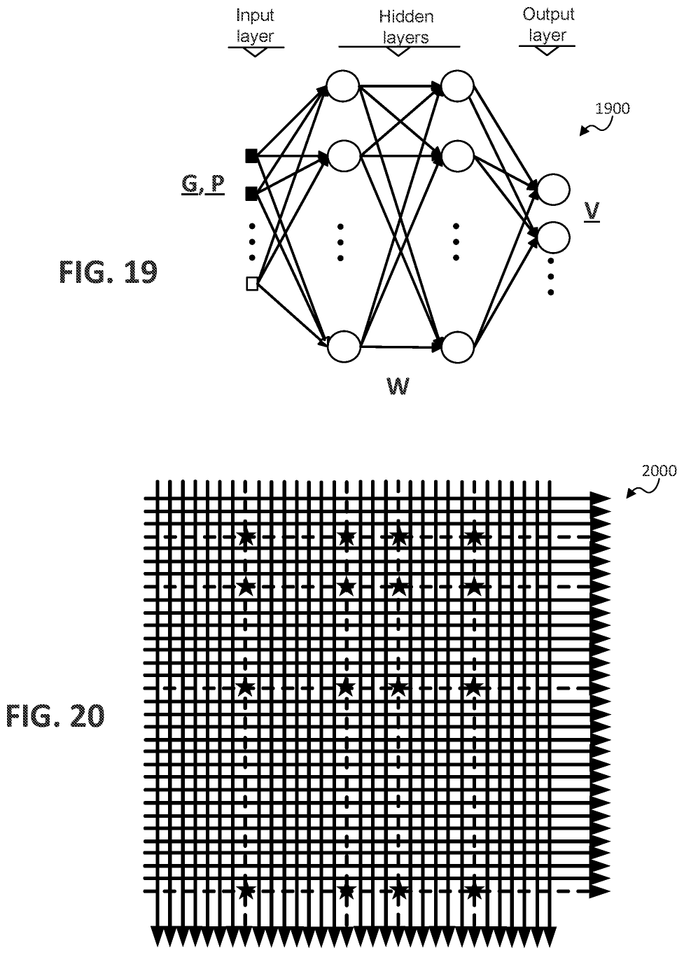

FIG. 19 is a diagram illustrating an example multi-perceptron DNN 1900 for the sequential tracking read thresholds estimation, according to various arrangements. The DNN 1900 can receive more variety of input features as compared to linear estimators. The DNN 1900 can receive the input features G which is the read histogram (e.g., 410 and 1510) and directional FBC (e.g., 420 and 1520) and P which is additional features such as a physical row number, program/erase cycle count, read disturb count, input read thresholds, and so on. The input features (e.g., vector) P can include all of those types of features, some but not all types of features as they become available for the controller during a sequential read operation.

In some examples, for linear estimation technique, the read threshold estimator can handle any input thresholds generating its input features. In some arrangements, the read threshold estimator can be iteratively trained. For an initial training iteration, read operations are performed for every block using normal thresholds. Thus, in the initial training iteration, a database is formed using normal read histograms and their directional FBC information under various stress conditions. From this initial training iteration, a temporary coefficient matrix (suitable only for normal read inputs) is obtained. In some examples, there is a strong linear dependency (although actual dependency is nonlinear) between a read histogram and the optimal read thresholds. The directional errors relationship to the optimal read thresholds can be highly nonlinear. Thus, the directional error inputs can be incorporated in several variations to determine the best candidate for a linear fit (combined with the 16 read histogram features) to the optimal read thresholds.

In some arrangements, various types of tracking estimator setups can be used for training the estimator. For example, “no features” refers to no added directional FBC features (0 additional features, overall 16 FBC features), with coefficient matrix X_{15×16}. In some examples, “directionalErrs” refers to a number of errors from r.h.s. and l.h.s. of each threshold (30 additional features, overall 46 FBC features), with coefficient matrix X_{15×46}. In some examples, “directionalErrsRatio” refers to a ratio of r.h.s./l.h.s. errors, e.g., zero errors changed to one to avoid singularity, (15 additional features, overall 31 FBC features), with coefficient matrix X_{15×31}. In some examples, “directionalErrsLogRatio” refers to a log ratio of r.h.s./l.h.s. errors e.g., zero errors changed to one to avoid singularity, (15 additional features, overall 31 FBC features), with coefficient matrix X_{15×31}. In some examples, “THerrs” refers to a number of errors of each threshold (15 additional features, overall 31 FBC features), with coefficient matrix X_{15×31}. In some examples, “PAGEerrs” refers to a number of errors of each page (4 additional features, overall 20 FBC features), with coefficient matrix X_{15×20}, leading to reduced computational complexity compared to per threshold directional errors given that only page errors are used. In some examples, “PAGEdirectionalErrs” refers to a number of 1→0 and 0→1 errors of each page (8 additional features, overall 24 FBC features), with coefficient matrix X_{15×24}, leading to reduced computational complexity compared to per threshold directional errors given that only page errors are used. In some examples, “PAGEdirectionalErrsRatio” refers to a ratio of number of 1→0 and 0→1 errors of each page (4 additional features, overall 20 FBC features), with coefficient matrix X_{15×20}, leading to reduced computational complexity compared to per threshold directional errors given that only page errors are used. In some examples, “PAGEdirectionalErrsLogRatio” refers to a log ratio of number of 1→0 and 0→1 errors of each page (4 additional features, overall 20 FBC features), with coefficient matrix X_{15×20}, leading to reduced computational complexity compared to per threshold directional errors given that only page errors are used. In some examples, “PAGEdirectionalErrsWithLogRatio” refers to an actual number and log ratio of number of 1→0 and 0→1 errors of each page (12 additional features, overall 28 FBC features), with coefficient matrix X_{15×28}, leading to reduced computational complexity compared to per threshold directional errors given that only page errors are used.

For any training setup in which FBC information is used, the input features are normalized by dividing the input columns by their std, e.g., x/std(x), where x is an input column (feature) of the estimator. For each training setup, a linear estimator coefficient matrix is obtained using the QT-type Weighted Least Squares (WLS) estimation algorithm described with normal thresholds inputs. The results of some of the setups can be close to those of the QT method.

In some examples, accurate FBC information is available after successful decoding. If after decoding failure sequential tracking is still applied, only pre-decode read histogram (and possibly input read thresholds) can be used as input features. Alternatively, the directional FBC information can still be used, although its inaccuracy should still be taken into account. In some examples, partial FBC information can be extracted despite decoding failure.

In some examples, the error vector information that is used for tracking can be efficiently used by the tracking estimator even if this error vector is not fully accurate, given that the tracking process is based on statistical information. In some code structures (e.g., Bose-Chaudhuri-Hocquenghem (BCH) codes), in case of decoding failure, there is no information about the error vector so FBC information is not available. In contrast, in other code structures, such as in product code, the code structure is based on multiple code components. In this case, during the decoding process, the code components are solved iteratively. In case that all code components are solved successfully, the decoding is finished successfully and the error vector (all errors in the original code word) is available. In case of decoding failure, some code components were not decoded successfully. However, in case that some or most of the code components were decoded successfully (number of unsolved code components is less than a threshold), then most of the errors in the original code word are available and this information may be sufficient to provide accurate tracking.

FIG. 20 is a diagram illustrating an example product code 2000 used to obtain suboptimal error vector under decoding failure, according to various arrangements. The product code 1100 can be used for providing partial FBC information. For example, the original code word is made of 32×32 code components with overall 64 code components. Each code component can fix t=3 errors. In some examples, during the iterative decoding, many errors (above a suitable threshold) were fixed on the code components represented by solid lines. In the stopping set, there are 16 errors (marked with stars) that cannot be solved using turbo decoding. As a result, decoder result is “decoding failure” with 8 unsolved code components (dashed lines). The errors vector information from the code components that were fixed with high probability, which are represented by the black lines, is available and may be sufficient for the tracking process.

In some arrangements, the sequential read threshold tracking methods described herein can derive accurate suboptimal read thresholds for a target block during or in connection with a sequential read, to reduce the BER and avoid decoding errors within that sequential read in addition to future reads from this target block.

In some examples, a sequential read threshold tracking method includes performing all page reads from a target row, decode, and save all results to buffers. For example, a sequential read operation includes reading pages (e.g., consecutive pages) of a target row of the block, decoding the read data, and save the results to the buffers. The controller determines information on a number of errors for at least a portion of a page for performing a sequential read operation of a plurality of pages of a block of a plurality of blocks of the non-volatile memory. The data is read using a first read threshold.

In some examples, determining the information on the number of errors for at least the portion of the page includes obtaining read data by performing the sequential read operation on the plurality of pages using the first read threshold and obtaining fixed data and the information on the number of the errors for at least the portion of the page in response to decoding the read data.

The sequential read threshold tracking method further includes generate pre-decode read histogram from buffered page reads. The updated or estimated read threshold (e.g., the second read threshold) is determined based at least in part on the read histogram for the sequential read operation and the directional FBC information (e.g., the information on the number of the errors for at least the portion of the page).

In case of successful decoding, we extract directional FBC information that includes the overall number of errors per threshold as well as their directions (e.g., r.h.s. or l.h.s.). The directional FBC information is saved (e.g., in the buffer 910 and 920 and/or another suitable memory of the controller). In case of failed decoding the sequential tracking can still be applied using partial FBC information.

In some examples, the FBC input features may not include number of errors per threshold from each side. For example, only FBC per threshold (and not directional), only FBC per page, and so on can be used. In addition to the read histogram and FBC information, the read thresholds used on the target row can be an additional input for the estimator 430 or 1530. In some examples, the read histogram, the error information, and in some cases the initial read thresholds (e.g., the first read thresholds) are used to estimate the read thresholds of a target row and use the estimated thresholds to update read thresholds for the entire block.

In some examples, the sequential read threshold tracking method can use any arbitrary input thresholds, and an iterative training method used to train (e.g., update) the tracker (e.g., the estimator 430/1530) starting with normal read inputs. Then, each estimation results of a current training iteration is used as input for future training iterations until convergence is obtained under a predefined metric.

In some arrangements, the buffering of pages can be performed on a single physical block per tracking update at a time and perform a round-robin selection of blocks for update according to relevant blocks during sequential reads. In some arrangements, the thresholds estimation is performed on a single NAND block and thresholds update can be applied to all NAND blocks that are part of the sequential read (since they were all written together, and probably undergo same stress).

By using more accurate read thresholds during sequential read of a target block, the BER can be significantly reduced and overall system performance (e.g., in terms of throughput) can be improved. The sequential read threshold tracking methods described herein are low-complexity, accurate, and have low memory requirements.

In some arrangements, instead of read thresholds estimation, the sequential read tracking method can be used to classify the best read thresholds for a target block from a finite set of classes. The sequential tracking of a target block can also be performed as a Kalman-type filter. In this case, the decoding statistics per read command along the same block are used to apply recursive read thresholds update taking into account all historical statistics of same block and current read result. The target may be either continuous refinement of read thresholds from a finite set or actual read thresholds estimation.

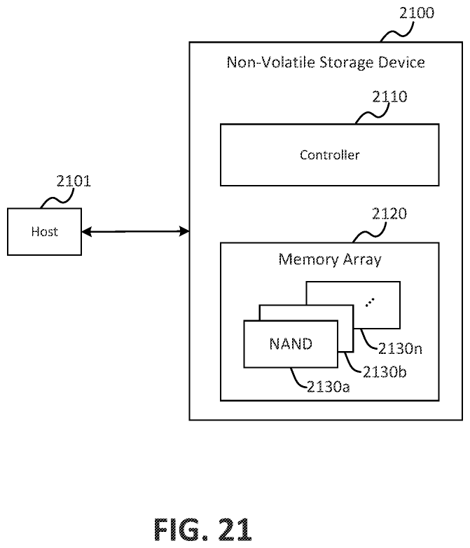

To assist in illustrating the present implementations, FIG. 21 shows a block diagram of a system including a non-volatile storage device 2100 coupled to a host 2101 according to some implementations. In some examples, the host 2101 can be a user device operated by a user. The host 2101 may include an operating system (OS), which is configured to provision a filesystem and applications which use the filesystem. The filesystem communicates with the non-volatile storage device 2100 (e.g., a controller 2110 of the non-volatile storage device 2100) over a suitable wired or wireless communication link or network to manage storage of data in the non-volatile storage device 2100. In that regard, the filesystem of the host 2101 sends data to and receives data from the non-volatile storage device 2100 using a suitable interface to the communication link or network.

In some examples, the non-volatile storage device 2100 is located in a datacenter (not shown for brevity). The datacenter may include one or more platforms, each of which supports one or more storage devices (such as but not limited to, the non-volatile storage device 2100). In some implementations, the storage devices within a platform are connected to a Top of Rack (TOR) switch and can communicate with each other via the TOR switch or another suitable intra-platform communication mechanism. In some implementations, at least one router may facilitate communications among the non-volatile storage devices in different platforms, racks, or cabinets via a suitable networking fabric. Examples of the non-volatile storage device 2100 include but are not limited to, a solid state drive (SSD), a non-volatile dual in-line memory module (NVDIMM), a Universal Flash Storage (UFS), a Secure Digital (SD) device, and so on.

The non-volatile storage device 2100 includes at least a controller 2110 and a memory array 2120. Other components of the non-volatile storage device 2100 are not shown for brevity. The memory array 2120 includes NAND flash memory devices 2130a-2130n. Each of the NAND flash memory devices 2130a-2130n includes one or more individual NAND flash dies, which are non-volatile memory capable of retaining data without power. Thus, the NAND flash memory devices 2130a-2130n refer to multiple NAND flash memory devices or dies within the flash memory device 2100. Each of the NAND flash memory devices 2130a-2130n includes one or more dies, each of which has one or more planes. Each plane has multiple blocks, and each block has multiple pages.

While the NAND flash memory devices 2130a-2130n are shown to be examples of the memory array 2120, other examples of non-volatile memory technologies for implementing the memory array 2120 include but are not limited to, dynamic random access memory (DRAM), magnetic random access memory (MRAM), phase change memory (PCM), ferro-electric RAM (FeRAM), and so on. The ECC structure described herein can be likewise implemented on memory systems using such memory technologies and other suitable memory technologies.

Examples of the controller 2110 include but are not limited to, an SSD controller (e.g., a client SSD controller, a datacenter SSD controller, an enterprise SSD controller, and so on), a UFS controller, or an SD controller, and so on. The controller 1700 is an example implementation of the controller 2110. The controller 2110 can combine raw data storage in the plurality of NAND flash memory devices 2130a-2130n such that those NAND flash memory devices 2130a-2130n function as a single storage. The controller 2110 can include microcontrollers, buffers, error correction systems, Flash Translation Layer (FTL) and flash interface modules. As described herein, the controller 2110 can further include the read threshold estimator 430/1530, the buffers 900, the histogram engine 1730, and so on. Such functions can be implemented in HW, Software (SW), and FW or any combination thereof. In some arrangements, the SW/FW of the controller 2110 can be stored in the non-volatile storage device 2100 or in any other suitable computer readable storage medium.

The controller 2110 includes suitable processing and memory capabilities for executing functions described herein, among other functions. As described, the controller 2110 manages various features for the NAND flash memory devices 2130a-2130n including, but not limited to, I/O handling, reading, writing/programming, erasing, monitoring, logging, error handling, garbage collection, wear leveling, logical to physical address mapping, data protection (encryption/decryption), and the like. Thus, the controller 2110 provides visibility to the NAND flash memory devices 2130a-2130n.

The error correction systems of the controller 2110 can include or otherwise implement one or more ECC encoders and one or more ECC decoders, collectively referred to as an ECC encoder/decoder. The ECC encoders are configured to encode data (e.g., input payload) to be programmed to the NAND flash memory devices 2130a-2130n using the ECC structures described herein. The ECC decoders are configured to decode the encoded data to correct programming errors, errors caused by reading with non-optimal thresholds, errors caused by retention/read-disturb stresses, and so on, in connection with a read operation. To enable low-complexity processing, the ECC encoder/decoder is implemented on hardware and/or firmware of the controller 2110.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout the previous description that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is understood that the specific order or hierarchy of steps in the processes disclosed is an example of illustrative approaches. Based upon design preferences, it is understood that the specific order or hierarchy of steps in the processes may be rearranged while remaining within the scope of the previous description. The accompanying method claims present elements of the various steps in a sample order, and are not meant to be limited to the specific order or hierarchy presented.

The previous description of the disclosed implementations is provided to enable any person skilled in the art to make or use the disclosed subject matter. Various modifications to these implementations will be readily apparent to those skilled in the art, and the generic principles defined herein may be applied to other implementations without departing from the spirit or scope of the previous description. Thus, the previous description is not intended to be limited to the implementations shown herein but is to be accorded the widest scope consistent with the principles and novel features disclosed herein.

The various examples illustrated and described are provided merely as examples to illustrate various features of the claims. However, features shown and described with respect to any given example are not necessarily limited to the associated example and may be used or combined with other examples that are shown and described. Further, the claims are not intended to be limited by any one example.

The foregoing method descriptions and the process flow diagrams are provided merely as illustrative examples and are not intended to require or imply that the steps of various examples must be performed in the order presented. As will be appreciated by one of skill in the art the order of steps in the foregoing examples may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the examples disclosed herein may be implemented or performed with a general purpose processor, a DSP, an ASIC, an FPGA or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some steps or methods may be performed by circuitry that is specific to a given function.

In some examples, the functions described may be implemented in hardware, software, firmware, or any combination thereof. If implemented in software, the functions may be stored as one or more instructions or code on a non-transitory computer-readable storage medium or non-transitory processor-readable storage medium. The steps of a method or algorithm disclosed herein may be embodied in a processor-executable software module which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed examples is provided to enable any person skilled in the art to make or use the present disclosure. Various modifications to these examples will be readily apparent to those skilled in the art, and the generic principles defined herein may be applied to some examples without departing from the spirit or scope of the disclosure. Thus, the present disclosure is not intended to be limited to the examples shown herein but is to be accorded the widest scope consistent with the following claims and the principles and novel features disclosed herein.

What is claimed is:

1. A system, comprising:
a non-volatile memory; and
a controller operatively coupled to the non-volatile memory, wherein the controller is to:
determine information on a number of errors for at least a portion of a page for performing a sequential read operation of a plurality of pages of a block of a plurality of blocks of the non-volatile memory, wherein the data is read using a first read threshold;
determine a second read threshold based at least in part on read histogram for the sequential read operation and the information on the number of the errors for at least the portion of the page.

2. The system of claim 1, wherein the plurality of pages are consecutive pages of the block.

3. The system of claim 1, wherein the information on the number of the errors for at least the portion of the page comprises a Failed Bit Count (FBC) value and a direction of the errors.

4. The system of claim 3, wherein the direction of the errors comprises:
a right hand side (r.h.s.) error corresponding a voltage located on a right side of the first threshold along a voltage axis; and
a left hand side (l.h.s.) error corresponding a voltage located on a left side of the first threshold along the voltage axis, wherein the voltage axis increases in voltage from the left side to the right side.

5. The system of claim 1, wherein the number of errors for at least a portion of the page comprises an actual number of errors for a give size of the portion of the page.

6. The system of claim 1, wherein determining the information on the number of errors for at least the portion of the page comprises:
obtaining read data by performing the sequential read operation on the plurality of pages using the first read threshold; and
obtaining fixed data and the information on the number of the errors for at least the portion of the page in response to decoding the read data.

7. The system of claim 1, further comprising saving read data from the sequential read operation and the information on the number of errors for at least the portion of the page in a plurality of buffers.

8. The system of claim 7, wherein the plurality of buffers comprises:
a plurality of data buffers for buffering the read data;
an error flag buffer; and
an error direction buffer.

9. The system of claim 1, wherein the second read threshold is determined based at least in part on the read histogram for the sequential read operation, the information on the number of the errors for at least the portion of the page, and the first read threshold.

10. The system of claim 1, wherein the second read threshold is determined for a row of the plurality of pages.

11. The system of claim 1, wherein the controller is to update the first read threshold with the second read threshold for the block.

12. The system of claim 1, wherein the second read threshold is determined by an estimator, wherein the estimator is updated using an iterative training method in which an output of the estimator for an iteration of the iterative training method is used as an input to a subsequent iteration of the iterative training method.

13. The system of claim 1, wherein the controller is to buffer read data from the sequential read operation of a plurality of blocks comprising the block, one block at a time.

14. The system of claim 1, wherein the controller is to apply the second read threshold to another block, the block and the another block are of the same sequential read operation.

15. The system of claim 1, wherein
historical second read thresholds for the block are saved;
the second read threshold is determined based at least in part of the read histogram, the information on the number of the errors for at least the portion of the page, and the historical second read thresholds;
at least one an estimator or classifier is used to determine the second read threshold; and
a function is applied on the number of the errors as an input for the estimator.

16. The system of claim 1, wherein the second read threshold is determined using a read threshold estimator, the read threshold estimator comprises a linear estimator, a Kalman-type filter or a Deep Neural Network (DNN).

17. At least one non-transitory computer readable medium including one or more instructions stored thereon and executable by a processor to:
determine information on a number of errors for at least a portion of a page for performing a sequential read operation of a plurality of pages of a block of a plurality of blocks of a non-volatile memory, wherein the data is read using a first read threshold;
determine a second read threshold based at least in part on read histogram for the sequential read operation and the information on the number of the errors for at least the portion of the page.

18. The at least one non-transitory computer readable medium of claim 17, wherein
the information on the number of the errors for at least the portion of the page comprises a Failed Bit Count (FBC) value and a direction of the errors; and
the direction of the errors comprises:
a right hand side (r.h.s.) error corresponding a voltage located on a right side of the first threshold along a voltage axis; and
a left hand side (l.h.s.) error corresponding a voltage located on a left side of the first threshold along the voltage axis, wherein the voltage axis increases in voltage from the left side to the right side.

19. A method, comprising:
determining information on a number of errors for at least a portion of a page for performing a sequential read operation of a plurality of pages of a block of a plurality of blocks of a non-volatile memory, wherein the data is read using a first read threshold;
determining a second read threshold based at least in part on read histogram for the sequential read operation and the information on the number of the errors for at least the portion of the page.

20. The method of claim 19, wherein
the information on the number of the errors for at least the portion of the page comprises a Failed Bit Count (FBC) value and a direction of the errors; and
the direction of the errors comprises:
a right hand side (r.h.s.) error corresponding a voltage located on a right side of the first threshold along a voltage axis; and
a left hand side (l.h.s.) error corresponding a voltage located on a left side of the first threshold along the voltage axis, wherein the voltage axis increases in voltage from the left side to the right side.
